(19) United States
(12) Patent Application Publication
(10) Pub. No.: US 2025/0209377 A1
(43) Pub. Date: Jun. 26, 2025

(54) HIGH-PRECISION MEASUREMENT SYSTEM, CALIBRATION METHOD AND NON-TRANSITORY COMPUTER READABLE STORAGE MEDIUM

(71) Applicant: CHROMA ATE INC., Taoyuan City (TW)

(72) Inventors: Chih-Hsien WANG, Taoyuan City (TW); Wei-Jhe HONG, Taoyuan City (TW); Chih-Wei LAI, Taoyuan City (TW); Kun-Che HE, Taoyuan City (TW); Kuo-Chu HU, Taoyuan City (TW)

(21) Appl. No.: 18/940,782

(22) Filed: Nov. 7, 2024

(30) Foreign Application Priority Data
Dec. 26, 2023 (TW) 112150794

(51) Int. Cl. G06N 20/00

(52) U.S. Cl. CPC G06N 20/00

(57) ABSTRACT

A high-precision measurement system is disclosed. The high-precision measurement system includes a data collection circuit, a machine learning circuit, and an output circuit. The data collection circuit is configured to obtain several first output data corresponding to several first setting data. The machine learning circuit is configured to create a machine learning model according to the several first setting data, the several first output data, and several first correction parameters between the several first setting data and the several first output data, and the machine learning circuit is configured to generate a second correction parameter corresponding to a second setting data according to the machine learning model. The output circuit is configured to correct a second output data corresponding to the second setting data to generate a corrected output data according to the second correction parameter.

### CROSS-REFERENCE TO RELATED APPLICATION

This application claims priority to Taiwan Application Serial Number 112150794, filed Dec. 26, 2023, which is herein incorporated by reference in its entirety.

### BACKGROUND

### Field of Disclosure

The present disclosure relates to a high-precision measurement system, a calibration method, and a non-transitory computer readable storage medium. Specifically, the present disclosure relates to a high-precision measurement system, a calibration method, and a non-transitory computer readable storage medium calibrated through machine learning model.

### Description of Related Art

Before electronic equipment or electronic components leave the factory, an electronic measurement system must be used to measure the electrical properties of the electronic equipment or electronic components. That is, the electronic measurement system will provide the electrical energy required by the electronic equipment or electronic components, and according to feedback signals from electronic equipment or electronic components, whether the electronic equipment or electronic components are functioning properly is verified.

However, due to factors such as hardware circuitry, ambient temperature, and ambient humidity, there is an error between the actual output power of the electronic measurement system and the set output power. Therefore, it is necessary to measure the electronic measurement by measuring feedback signals. The actual output power of the system is corrected so that the actual output power of the electronic measurement system is consistent with the set output power.

Conventionally, when the actual output power and the set output power are linearly related, the point-slope method can be used to correct the actual output power. However, in practice, the relationship between the actual output power and the set output power is not linear. Therefore, if the point-slope method is used for correction, optimal correction will not be achieved.

### SUMMARY

The summary is intended to provide a simplified summary of the disclosure to provide the reader with a basic understanding of the disclosure. The summary is not an extensive overview of the disclosure, and it is not intended to identify key/critical elements of the embodiments or to delineate the scope of the disclosure.

The disclosure provides a high-precision measurement system. The high-precision measurement system includes a data collection circuit, a machine learning circuit, and an output circuit. The data collection circuit is configured to obtain several first output data corresponding to several first setting data. The machine learning circuit is coupled to the data collection circuit. The machine learning circuit is configured to create a machine learning model according to the several first setting data, the several first output data, and several first correction parameters between the several first setting data and the several first output data, and the machine learning circuit is configured to generate a second correction parameter corresponding to a second setting data according to the machine learning model. The output circuit is coupled to the machine learning circuit. The output circuit is configured to correct a second output data corresponding to the second setting data to generate a corrected output data according to the second correction parameter.

The disclosure provides a calibration method. The calibration method is suitable for a high-precision measurement system. The calibration method includes the following operations: obtaining several first setting data, several first output data and several first correction parameters between the several first setting data and the several first output data; creating a machine learning model according to the several first setting data, the several first output data and the several first correction parameters; generating a second correction parameter corresponding to a second setting data according to the machine learning model; and correcting a second output data corresponding to the second setting data to generate a corrected output data according to the second correction parameter.

The disclosure provides a non-transitory computer readable storage medium. The non-transitory computer readable storage medium includes one or more computer programs stored therein, and the one or more computer programs can be executed by one or more processors so as to be configured to operate the above mentioned calibration method.

### BRIEF DESCRIPTION OF THE DRAWINGS

FIG. 1 is a schematic diagram illustrating a high-precision measurement system according to some embodiments of the present disclosure.

FIG. 2 is a flow chart illustrating a calibration method according to some embodiments of the present disclosure.

FIG. 3 is a schematic diagram illustrating a calibration method according to some embodiments of the present disclosure.

FIG. 4 is a schematic diagram illustrating a machine learning circuit according to some embodiments of the present disclosure.

In accordance with common practice, the various features and components in the drawings are not drawn to scale, but are drawn in such a way as to best present the specific features and components relevant to the embodiments of the present disclosure. In addition, the same or similar reference symbols are used to refer to similar elements/components in different drawings.

### DETAILED DESCRIPTION

In order to make the description of the embodiments of the present disclosure more detailed and complete, the following provides an illustrative description of the implementation aspects and specific embodiments of the present disclosure; but this is not the only form of implementing or the specific embodiments of the present disclosure. The embodiments of the present disclosure covers the characteristics of several specific embodiments and the methods and operations configured to construct and operate these specific embodiments and their sequences. However, other specific embodiments may also be used to achieve the same or equivalent functions and operation sequences.

Unless otherwise defined in this specification, the meanings of scientific and technical terms used here are the same as those commonly understood and customary by those with ordinary knowledge in the technical field to which the embodiments of the present disclosure belongs. In addition, unless there is conflict with the context, the singular noun used in this specification covers the plural form of the noun; and the plural noun used also covers the singular form of the noun.

In addition, “coupling” as used in the embodiments of the present disclosure can refer to two or several components that are in direct physical or electrical contact with each other, or that are in indirect physical or electrical contact with each other, or can also refer to the mutual operation or action of two or several components.

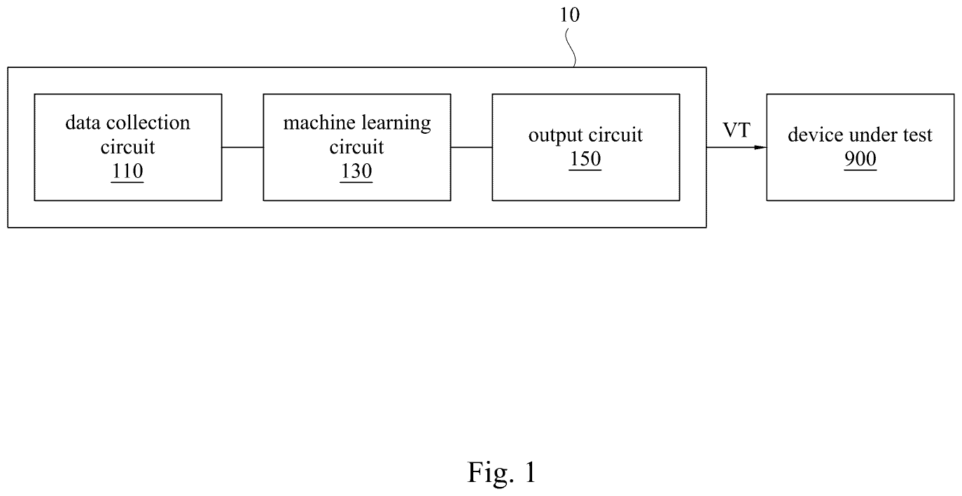

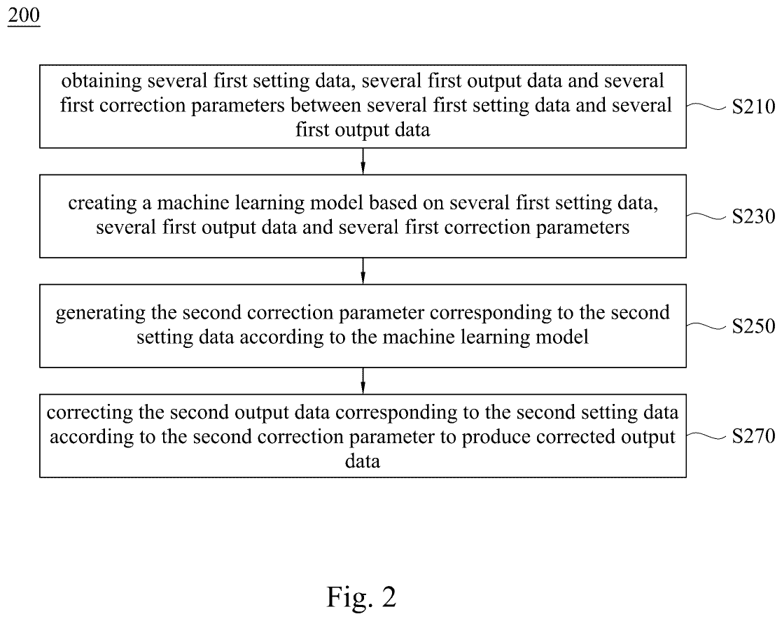

FIG. 1 is a schematic diagram illustrating a high-precision measurement system 10 according to some embodiments of the present disclosure. As shown in the figure, the high-precision measurement system 10 includes a data collection circuit 110, a machine learning circuit 130 and an output circuit 150. In the connection relationship, the machine learning circuit 130 is coupled to the data collection circuit 110, and the output circuit 150 is coupled to the machine learning circuit 130. The operation method of the high-precision measurement system 10 will be explained below with reference to FIG. 2.

It should be noted that the embodiments of the present disclosure are not limited to the structure and operation shown in FIG. 1, which is only configured to illustrate one of the embodiments of the present disclosure, so that the technology of the embodiments of the present disclosure are easy to understand. The scope of the patent in the embodiments of the present disclosure shall be subject to the scope of the application. Without departing from the spirit of the embodiments of the present disclosure, modifications and embellishments made by those skilled in the art to the embodiments of the present disclosure will still fall within the scope of the patent application for the embodiments of the present disclosure.

FIG. 2 is a flow chart illustrating a calibration method 200 according to some embodiments of the present disclosure. To make the calibration method 200 easy to understand, reference is made to FIG. 1 together. The detailed process of the calibration method 200 will be introduced later.

In operation S210, several first setting data, several first output data and several first correction parameters between several first setting data and several first output data are obtained. In some embodiments, operation S210 is performed by the machine learning circuit 130 in FIG. 1.

Reference is made to FIG. 1 together. In an embodiment, the output circuit 150 of the high-precision measurement system 10 generates and outputs the output voltage VT to the device under test 900 according to the first setting data. For example, in an embodiment, a user operates the operation interface (not shown) of the high-precision measurement system 10 and sets the first setting data to 10 volts. It is expected that the output circuit 150 of the high-precision measurement system 10 outputs an output voltage VT of 10 volts to the device under test 900. However, the actual output voltage VT output by the output circuit 150 may be different from the setting data (10 volts) due to internal circuits or environmental temperature, humidity and other factors, that is, the actual output voltage is not 10 volts. The above output voltage VT is the output data generated and output corresponding to the setting data.

For example, in an embodiment, the output voltage VT generated and output by the output circuit 150 is 9.7 volts according to the setting data of 10 volts. The output voltage VT generated and output by the output circuit 150 is 20.3 volts according to the setting data of 20 volts. The data collection circuit 110 collects the above setting data and its corresponding output data (output voltage VT).

In some embodiments, after the high-precision measurement system 10 generates and outputs the output voltage VT of several different voltage values according to several different first setting data, the voltage value of the output voltage VT obtained by the data collection circuit 110 is obtained through an external circuit (not shown). Then, it is fed back to the data collection circuit 110 through an external circuit.

Next, after the machine learning circuit 130 obtains the above-mentioned several different setting data and the several first output data in correspondence, several first correction parameters between several setting data and their corresponding several first output data with different voltage values are calculated in the form of point-slope correction. In some embodiments, several first correction parameters include several gain values and several offset values.

In some embodiments, after corrected by the correction parameter, the resulting corrected output data is the same as the setting data. That is, when the setting data is 10 volts, the corrected output data is also 10 volts.

In some embodiments, the calculation formula of point-slope correction is as formula (1) as follows.

$$Y = AX + B . \qquad Formula ( 1 )$$

In the above formula (1), Y is corrected output data, X is first output data, A is gain value, and B is offset value. Through point-slope correction, the output data can be corrected into corrected output data.

The above formula (1) is for illustration only. In some other embodiments, the first correction parameters may include several correction formulas, several gain values and several offset values.

In operation S230, a machine learning model is created based on several first setting data, several first output data and several first correction parameters. In some embodiments, operation S230 is performed by the machine learning circuit 130 in FIG. 1.

In some embodiments, the machine learning model includes a lookup table stored in memory (not shown).

In an embodiment, the first correction parameters (including gain values and offset values) and corrected output data calculated by machine learning circuit 130 based on several different first setting data and their corresponding first output data are shown in the following lookup table 1.

Lookup table 1.

| first setting | first output | | | |
|---|---|---|---|---|
| data (Unit: | data (Unit: | | | corrected output |
| Volt) | Volt) | gain value | offset value | data (Unit: Volt) |
| 5 | 4.8 | a1 | b1 | 5 |
| 10 | 9.7 | a2 | b2 | 10 |
| 20 | 20.3 | a3 | b3 | 20 |
| 30 | 31 | a4 | b4 | 30 |
| 40 | 40.8 | a5 | b5 | 40 |
| 50 | 49.7 | a6 | b6 | 50 |

The first output data in the above lookup table 1 is several first setting data obtained by the data collection circuit 110 of the high-precision measurement system 10 and the first output data corresponding to the first setting data. After correction according to the above formula (1) through the gain value and offset value, the first output data is corrected to be the corrected output data, so that the corrected output data is the same as the first setting data, as shown in lookup table 1 above.

In some embodiments, since the error between first setting data and first output data is nonlinear, the first correction parameter corresponding to different first setting data and first output data is also different.

In one another embodiment, The above lookup table 1 is the first setting data, first output data and the corresponding first correction parameter obtained when the output current of the high-precision measurement system 10 is the first current value (for example, 5 amps). In one another embodiment, the machine learning circuit 130 can create another lookup table based on the first setting data, the first output data, and the corresponding first correction parameter obtained when the output current of the high-precision measurement system 10 is the second current value (for example, 10 amps). That is to say, the setting data and its corresponding output data can be voltage value/current value/power value, etc. The above lookup table 1 only uses voltage value as an example for explanation.

In some embodiments, when creating the machine learning model, the machine learning circuit 130 is further configured to generate a lookup table based on the several environmental data obtained by the data collection circuit 110, the first correction parameters (including gain values and offset values) calculated based on the several different first setting data and their corresponding first output data, and the environmental data obtained by the data collection circuit 110, so as to create the machine learning model.

For example, assume that the above lookup table was created when the ambient temperature is 27 degrees Celsius and the ambient humidity is 70%. In the case of another ambient temperature and ambient humidity, the machine learning circuit 130 calculates the correction parameter based on the first setting data obtained in the case of another ambient temperature and ambient humidity and its corresponding first output data, and then creates another lookup table.

In this way, through creating several lookup tables, the machine learning circuit 130 creates the machine learning model. In addition, the lookup table mentioned above is the lookup table of the output voltage VT. In some other embodiments, the lookup table created by machine learning circuit 130 can be based on the setting data and output data of the output current of high-precision measurement system 10, can be setting data and output data based on the output current and output voltage of the high-precision measurement system 10 at the same time, can be a lookup table created based on the input current setting data and output data of the high-precision measurement system 10, can be a lookup table created based on the setting data and output data of the input voltage of the high-precision measurement system 10, can also be a lookup table created based on the input current and input voltage setting data and output data of the high-precision measurement system 10. The embodiments of the present disclosure are not limited to the above.

In operation S250, the second correction parameter corresponding to the second setting data is generated according to the machine learning model. In some embodiments, the operation S250 is performed by the machine learning circuit 130 in FIG. 1.

In some embodiments, in operation S250, after the machine learning model is created, the machine learning circuit 130 inputs the second setting data to the machine learning model to obtain the second correction parameter corresponding to the second setting data. In some embodiments, the second setting data is the data set by the user through the operation interface (not shown) and input into the high-precision measurement system 10.

In some embodiments, the machine learning circuit 130 obtains at least two of the first correction parameters from the lookup table of the machine learning model based on the second setting data, and obtains the second correction parameter using the interpolation method.

In an embodiment, the machine learning circuit 130 obtains at least two first setting data that are closest to the second setting data from the lookup table of the machine learning model based on the second setting data, and based on the first correction parameter corresponding to at least two first setting data, the second correction parameter is obtained by the interpolation method.

For example, reference is made to lookup table 1 together. If in operation S250, the second setting data is 15 volts, then the machine learning circuit 130 obtains the first setting data that is closest to the second setting data, which is 10 volts and 20 volts. Then, the machine learning circuit 130 uses the interpolation method to learn that the gain value corresponding to the second setting data of 15 volts is (a2+a3)/2, and the offset value corresponding to the second setting data of 15 volts is (b2+b3)/2.

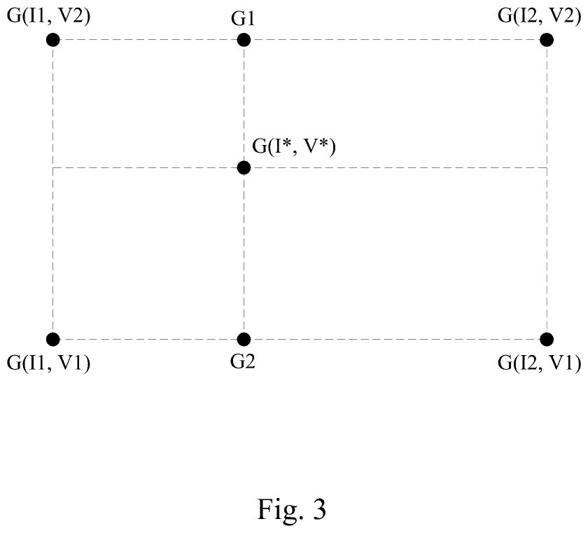

For further example, reference is made to FIG. 3 together. FIG. 3 is a schematic diagram illustrating a calibration method according to some embodiments of the present disclosure. G (I1, V2) in FIG. 3 is the gain value when the current value is I1 and the voltage value is V2 in the first setting data. G (I2, V2) is the gain value when the current value is I2 and the voltage value is V2 in the first setting data. G (I1, V1) is the gain value when the current value is I1 and the voltage value is V1 in the first setting data. And G (I2, V1) is the gain value when the current value is I2 and the voltage value is V1 in the first setting data.

The above gain values G (I1, V2), G (I2, V2), G (I1, V1) and G (I2, V1) are the gain values obtained by the machine learning circuit 130 based on the lookup table in the machine learning model, and the voltage values and current values in the above gain values G (I1, V2), G (I2, V2), G (I1, V1) and G (I2, V1) are the at least the two closest to the voltage value V* and current value I* of the gain value to be calculated G (I*, V*) in the lookup table. That is, current values I1 and I2 are the current values closest to the current value I* in the lookup table, and voltage values V1 and V2 are the voltage values closest to the voltage value V* in the lookup table.

Then, the machine learning circuit 130 obtains gain value G (I*, V*) of second setting data (i.e., current value I* and voltage value V*) based on the above gain values G (I1, V2), G (I2, V2), G (I1, V1) and G (I2, V1) and the following formula (2) to formula (5).

$$\frac{{I}^{*} - I 1}{I 2 - I 1} = \frac{G 1 - G ( I 1 , V 2 )}{G ( I 2 , V 2 ) - G ( I 1 , V 2 )} . \qquad Formula ( 2 )$$

$$G 1 = G ( I 1 , V 1 ) + \frac{{I}^{*} - I 1}{I 2 - I 1} [ G ( I 2 , V 2 ) - G ( I 1 , V 2 ] . \qquad Formula ( 3 )$$

$$G 2 = G ( I 1 , V 1 ) + \frac{{I}^{*} - I 1}{I 2 - I 1} [ G ( I 2 , V 1 ) - G ( I 1 , V 1 ] . \qquad Formula ( 4 )$$

$$G ( {I}^{*} , {V}^{*} ) = G 1 + ( \frac{{V}^{*} - V 1}{V 2 - V 1} ) ( G 2 - G 1 ) . \qquad Formula ( 5 )$$

In operation S270, the second output data corresponding to the second setting data is corrected according to the second correction parameter to produce corrected output data. In some embodiments, the operation S270 is performed by the output circuit 150 in FIG. 1.

In some embodiments, after the machine learning circuit 130 obtains the second correction data corresponding to the second setting data, the output circuit 150 corrects the second output data according to the second correction data to generate the corrected output data.

In some embodiments, the machine learning circuit 130 corrects the second output data using a point-slope formula (such as the above formula (1)).

For example, if the gain value corresponding to the second setting data of 15 volts obtained by the machine learning circuit 130 in operation S250 is

$$\frac{a 2 + a 3}{2} ,$$

and the offset value corresponding to the second setting data of 15 volts is

$$\frac{b 2 + b 3}{2} ,$$

the machine learning circuit 130 calculates the corrected output data according to equation (1) as follows:

$$Y 2 = \frac{a 2 + a 3}{2} \times X 2 + \frac{b 2 + b 3}{2} .$$

Y2 is corrected output data, X2 is second output data generated by output circuit 150 corresponding to second setting data 15 volts when being uncorrected

$$\frac{a 2 + a 3}{2}$$

is gain value,

$$\frac{b 2 + b 3}{2}$$

is offset value. Through point-slope correction, the second output data can be corrected so that the corrected output data is the same as the setting data.

In some embodiments, the output circuit 150 adjusts the second output data in a PWM (Pulse Width Modulation) manner according to the corrected output data to generate corrected output data. Various methods of adjusting the second output data are within the implementation of the present disclosure, and the implementation of the present disclosure is not limited to PWM.

It should be noted that the embodiments of the present disclosure are not limited to the operations shown in FIG. 2, which is only configured to illustrate one of the implementation methods of the present disclosure, so that the technology of the present disclosure is easy to understand, and the patent scope of the present disclosure shall be the scope of invention patent application shall prevail. Without departing from the spirit of the embodiments of the present disclosure, modifications and embellishments made by those skilled in the art to the embodiments of the embodiments of the present disclosure will still fall within the scope of the patent application for the invention of the embodiments of the present disclosure.

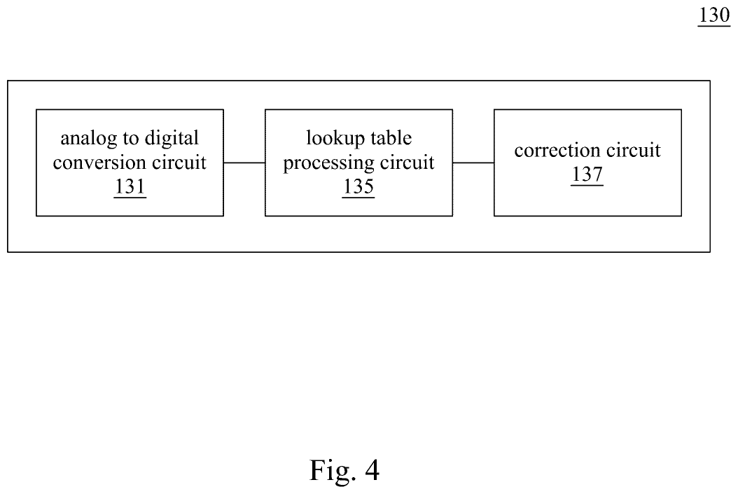

Reference is made to FIG. 4 together. FIG. 4 is a schematic diagram illustrating a machine learning circuit 130 according to some embodiments of the present disclosure. As illustrated in FIG. 4, the machine learning circuit 130 includes an analog to digital conversion circuit 131, a lookup table processing circuit 135 and a correction circuit 137. The lookup table processing circuit 135 is coupled to the analog to digital conversion circuit 131, and the correction circuit 137 is coupled to the lookup table processing circuit 135.

In some embodiments, the analog to digital conversion circuit 131 is configured to convert the output data obtained by data collection circuit 110 from analog data to digital data. The lookup table processing circuit 135 is configured to input the output data converted into digital data into the machine learning model to obtain the correction parameter. In some embodiments, the lookup table processing circuit 135 uses the moving average method to calculate the interpolation method to obtain the correction parameter.

The correction circuit 137 is configured to generate a PWM control signal according to the correction parameter, and configured to transmit the PWM control signal to the output circuit 150 as shown in FIG. 1, so that the output circuit 150 generates a corrected output signal according to the PWM control signal.

In some embodiments, the high-precision measurement system 10 further includes a memory (not shown) configured to store the machine learning model and lookup table for access by the machine learning circuit 130.

Through the operations of various embodiments described above, a high-precision measurement system, a calibration method, and a non-transitory computer readable storage medium are implemented. The high-precision measurement system and calibration method shown in the embodiments of the present disclosure use a machine learning model to calculate the correction parameter in response to changes in different environmental variables and circuit variables to correct the output data to corrected output data, so that the actual output data of the high-precision measurement system is the same as the setting data. In addition, the embodiments of the present disclosure can continuously learn, update and correct correction parameters through machine learning model. The above method can quickly obtain the correction parameter and effectively reduce the correction error.

In some embodiments, the machine learning circuit 130 as described above can be integrated into an electronic device or electronic system. In some embodiments, the server may be implemented as a cloud server, including a central processing unit. In some embodiments, a server may be, but is not limited to, a single processor or a collection of several microprocessors, and may include memory and I/O circuits.

In some embodiments, the machine learning circuit 130 may be a central processing unit (CPU), a microprocessor (MCU), a digital signal processor (DSP), a field programmable gate array (FPGA), or a server, or other computing circuits, processing circuits or components with data access, data calculation, data storage, data transmission and reception, or similar functions.

In some embodiments, the machine learning circuit 130 includes a processor and an input output circuit. A processor may be a circuit or component capable of data access, data computation, data storage, or similar functions. The input output circuit may be a circuit or component with data transmission and reception or similar functions.

In some embodiments, the data collection circuit 110 may be a current detection circuit, a voltage detection circuit, a temperature detection circuit, a humidity detection circuit, or other circuits or components with data detection, data transmission and reception, or similar functions. In some embodiments, the data collection circuit 110 obtains input data and environmental data through an external current detection circuit, voltage detection circuit, temperature detection circuit, humidity detection circuit or other circuits or components with similar functions.

In some embodiments, the high-precision measurement system 10 also includes a display circuit (not shown) configured to display setting data, output data, corrected output data, etc.

In some embodiments, the output circuit 150 may be a PWM driving circuit or other circuits or components with current output/voltage output/power output or other circuits or components with the same or similar functions.

Although the present disclosure has been described in considerable detail with reference to certain embodiments thereof, other embodiments are possible. Therefore, the scope of the appended claims should not be limited to the description of the embodiments contained herein. It will be apparent to those skilled in the art that various modifications and variations can be made to the structure of the present invention without departing from the scope or spirit of the invention.

What is claimed is:

1. A high-precision measurement system, comprising:
a data collection circuit, configured to obtain a plurality of first output data corresponding to a plurality of first setting data;
a machine learning circuit, coupled to the data collection circuit, configured to create a machine learning model according to the plurality of first setting data, the plurality of first output data, and a plurality of first correction parameters between the plurality of first setting data and the plurality of first output data, and configured to generate a second correction parameter corresponding to a second setting data according to the machine learning model; and
an output circuit, coupled to the machine learning circuit, configured to correct a second output data corresponding to the second setting data to generate a corrected output data according to the second correction parameter.

2. The high-precision measurement system of claim 1, wherein the plurality of first correction parameters comprise a plurality of gain values and a plurality of offset values.

3. The high-precision measurement system of claim 1, wherein the machine learning model further comprises a lookup table, wherein the lookup table is created according to the plurality of first setting data, the plurality of first output data and the plurality of first correction parameters.

4. The high-precision measurement system of claim 3, wherein the machine learning circuit is further configured to obtain at least two of the plurality of first correction parameters from the lookup table according to the second setting data, and use an interpolation method to obtain the second correction parameter.

5. The high-precision measurement system of claim 1, wherein the data collection circuit is further configured to obtain a plurality of environmental data, wherein the machine learning circuit is further configured to create the machine learning model according to the plurality of first setting data, the plurality of first output data, the plurality of first correction parameters, and the plurality of environmental data.

6. A calibration method, suitable for a high-precision measurement system, wherein the calibration method comprises:
obtaining a plurality of first setting data, a plurality of first output data and a plurality of first correction parameters between the plurality of first setting data and the plurality of first output data;
creating a machine learning model according to the plurality of first setting data, the plurality of first output data and the plurality of first correction parameters;
generating a second correction parameter corresponding to a second setting data according to the machine learning model; and
correcting a second output data corresponding to the second setting data to generate a corrected output data according to the second correction parameter.

7. The calibration method of claim 6, wherein the plurality of first correction parameters comprise a plurality of gain values and a plurality of offset values.

8. The calibration method of claim 6, further comprising:
creating a lookup table of the machine learning model according to the plurality of first setting data, the plurality of first output data and the plurality of first correction parameters.

9. The calibration method of claim 8, further comprising:
obtaining at least two of the plurality of first correction parameters from the lookup table according to the second setting data, and obtaining the second correction parameter by an interpolation method.

10. The calibration method of claim 6, further comprising:
obtaining a plurality of environmental data, and creating the machine learning model according to the plurality of first setting data, the plurality of first output data, the plurality of first correction parameters and the plurality of environmental data.

11. A non-transitory computer readable storage medium, wherein the non-transitory computer readable storage medium comprises one or more computer programs stored therein, and the one or more computer programs can be executed by one or more processors so as to be configured to operate a calibration method, wherein the calibration method comprises:
obtaining a plurality of first setting data, a plurality of first output data and a plurality of first correction parameters between the plurality of first setting data and the plurality of first output data;
creating a machine learning model according to the plurality of first setting data, the plurality of first output data and the plurality of first correction parameters;
generating a second correction parameter corresponding to a second setting data according to the machine learning model; and
correcting a second output data corresponding to the second setting data to generate a corrected output data according to the second correction parameter.

12. The non-transitory computer readable storage medium of claim 11, wherein the plurality of first correction parameters comprise a plurality of gain values and a plurality of offset values.

13. The non-transitory computer readable storage medium of claim 11, wherein the calibration method further comprises:
creating a lookup table of the machine learning model according to the plurality of first setting data, the plurality of first output data and the plurality of first correction parameters.

14. The non-transitory computer readable storage medium of claim 13, wherein the calibration method further comprises:
obtaining at least two of the plurality of first correction parameters from the lookup table according to the second setting data, and obtaining the second correction parameter by an interpolation method.

15. The non-transitory computer readable storage medium of claim 11, wherein the calibration method further comprises:
obtaining a plurality of environmental data, and creating the machine learning model according to the plurality of first setting data, the plurality of first output data, the plurality of first correction parameters and the plurality of environmental data.
